(19) United States
(12) Patent Application Publication
(10) Pub. No.: US 2025/0279615 A1
(43) Pub. Date: Sep. 4, 2025

(54) CABLE CONNECTOR ASSEMBLY HAVING LOCATING FEATURES

(71) Applicant: TE Connectivity Solutions GmbH, Schaffhausen (CH)

(72) Inventors: Albert Tsang, Harrisburg, PA (US); Michael James Horning, Landisville, PA (US)

(21) Appl. No.: 18/959,815

(22) Filed: Nov. 26, 2024

Related U.S. Application Data
(60) Provisional application No. 63/560,837, filed on Mar. 4, 2024.

(51) Int. Cl. H01R 13/631; H05K 7/14

(52) U.S. Cl. CPC H01R 13/6315; H05K 7/1454

(57) ABSTRACT

A connector assembly includes a connector holder having a frame holding a cable connector in a connector chamber. The cable connector includes a connector housing holding contact assemblies. The connector assembly includes a mounting assembly for mounting the connector holder to a panel. The mounting assembly includes a shaft, a biasing member operably coupled between the connector holder and the shaft, and a support element configured to be operably coupled between the shaft and the panel to support the shaft relative to the panel. The shaft is received in a locating opening and is undersized relative to the locating opening to allow a limited amount of floating movement in the locating opening in a float direction perpendicular to the mating direction to allow the connector holder and the cable connector to move relative to the panel.

### CROSS REFERENCE TO RELATED APPLICATIONS

This application claims benefit to U.S. Provisional Application No. 63/560,837, filed 4 Mar. 2024, titled “CABLE CONNECTOR ASSEMBLY HAVING LOCATING FEATURES”, the subject matter of which is herein incorporated by reference in its entirety.

### BACKGROUND OF THE INVENTION

The subject matter herein relates generally to communication systems.

Communication systems use electrical connectors to transmit data between components of the communication system. For example, electrical connectors may be held in a rack, chassis, cabinet or other system component. Mating connectors are mated to the electrical connectors. For example, the mating connectors may be mounted to a card assembly, such as a daughtercard or server card, which is plugged into the chassis. Proper mating of the mating connector with the electrical connector is necessary for proper operation of the communication system. For example, misalignment of the connectors may lead to damage to the contacts of the connectors. Additionally, partial mating of the connectors may lead to reduction in signal integrity due to partial mating of contacts and/or improper shielding of the signal contacts. In some systems, the server card may be mated with the assistance of a lever or other mechanical assist device to plug the server card into the chassis. Such mechanical loading of the server card may lead to damage to the electrical connector. Additionally, mounting of the electrical connectors within the rack may require special tools or mounting hardware, which adds cost and complexity to the system.

### BRIEF DESCRIPTION OF THE INVENTION

In one embodiment, a connector assembly is provided and includes a connector holder having a frame defining a connector chamber. The frame extends between a front and a rear of the connector holder. The frame includes an upper frame member, a lower frame member, and first and second side frame members extend between the upper and lower frame members to define the connector chamber. The connector assembly includes a cable connector received in the connector chamber. The cable connector includes a connector housing holding contact assemblies. Each contact assembly includes a signal contact and a cable terminated to the signal contact. The signal contact configured to be mated with a mating signal contact of a mating connector in a mating direction. The connector assembly includes a mounting assembly for mounting the connector holder to a panel. The mounting assembly includes a shaft, a biasing member operably coupled between the connector holder and the shaft, and a support element configured to be operably coupled between the shaft and the panel to support the shaft relative to the panel. The shaft configured to be received in a locating opening, wherein the shaft is undersized relative to the locating opening to allow a limited amount of floating movement in the locating opening in a float direction perpendicular to the mating direction to allow the connector holder and the cable connector to move relative to the panel. The biasing member forward biasing the cable connector and is compressible in a rearward compression direction parallel to the mating direction to allow the connector holder and the cable connector to move rearward relative to the panel.

In another embodiment, a connector assembly is provided and includes a connector holder having a frame defining a connector chamber. The frame extends between a front and a rear of the connector holder. The frame includes an upper frame member, a lower frame member, and first and second side frame members extend between the upper and lower frame members to define the connector chamber. The connector assembly includes a first cable connector received in the connector chamber. The first cable connector includes a first connector housing holding first contact assemblies. Each first contact assembly includes a first signal contact and a first cable terminated to the first signal contact. The first signal contact configured to be mated with a first mating signal contact of a first mating connector in a mating direction. The connector assembly includes a second cable connector received in the connector chamber. The second cable connector includes a second connector housing holding second contact assemblies. Each second contact assembly includes a second signal contact and a second cable terminated to the second signal contact. The second signal contact configured to be mated with a second mating signal contact of a second mating connector in a mating direction. The connector assembly includes a mounting assembly for mounting the connector holder to a panel. The mounting assembly includes a shaft, a biasing member operably coupled between the connector holder and the shaft, and a support element configured to be operably coupled between the shaft and the panel to support the shaft relative to the panel. The shaft configured to be received in a locating opening, wherein the shaft is undersized relative to the locating opening to allow a limited amount of floating movement in the locating opening in a float direction perpendicular to the mating direction to allow the connector holder and the cable connector to move relative to the panel. The biasing member forward biasing the cable connector and is compressible in a rearward compression direction parallel to the mating direction to allow the connector holder and the cable connector to move rearward relative to the panel.

In a further embodiment, a communication system is provided and includes a cartridge having panels forming a chamber. The panels include a front panel. The cartridge includes ports in the front panel at a front of the cartridge. The communication system includes connector assemblies received in the ports for mating with mating connector assemblies. Each connector assembly includes a connector holder, a cable connector held by the connector holder, and a mounting assembly for mounting the connector holder and the cable connector to the cartridge. Each connector holder has a frame defining a connector chamber. The frame extends between a front and a rear of the connector holder. The frame includes an upper frame member, a lower frame member, and first and second side frame members extend between the upper and lower frame members to define the connector chamber. Each cable connector is received in the corresponding connector chamber. Each cable connector includes a connector housing holding contact assemblies. Each contact assembly includes a signal contact and a cable terminated to the signal contact. The signal contact configured to be mated with a mating signal contact of a mating connector in a mating direction. Each mounting assembly includes a shaft, a biasing member operably coupled between the connector holder and the shaft, and a support element configured to be operably coupled between the shaft and the panels of the cartridge to support the shaft relative to the panels. The shaft configured to be received in a locating opening, wherein the shaft is undersized relative to the locating opening to allow a limited amount of floating movement in the locating opening in a float direction perpendicular to the mating direction to allow the connector holder and the cable connector to move relative to the panels. The biasing member forward biasing the cable connector and is compressible in a rearward compression direction parallel to the mating direction to allow the connector holder and the cable connector to move rearward relative to the panels.

### BRIEF DESCRIPTION OF THE DRAWINGS

FIG. 1 is a front view of a communication system in accordance with an exemplary embodiment.

FIG. 2 is a front view of a portion of the communication system in accordance with an exemplary embodiment.

FIG. 3 illustrates a portion of the communication system showing two of the cartridges in accordance with an exemplary embodiment.

FIG. 4 is a perspective view of a portion of the communication system showing one of the mating connector assemblies poised for coupling to the corresponding connector assembly in accordance with an exemplary embodiment.

FIG. 5 is a front perspective view of a portion of the communication system showing one of the connector assemblies in accordance with an exemplary embodiment coupled to the front panel of the cartridge.

FIG. 6 is a front perspective, exploded view of the connector assembly in accordance with an exemplary embodiment.

FIG. 7 is a front perspective view of a portion of the communication system showing one of the connector assemblies in accordance with an exemplary embodiment coupled to the front panel of the cartridge.

FIG. 8 is a front perspective, exploded view of the connector assembly in accordance with an exemplary embodiment.

FIG. 9 is a cross-sectional view of a portion of the communication system showing the connector assembly mounted to the front panel of the cartridge in accordance with an exemplary embodiment.

FIG. 10 is a perspective view of a portion of the communication system showing one of the connector assemblies in accordance with an exemplary embodiment.

FIG. 11 is a front perspective view of a portion of the communication system showing one of the connector assemblies in accordance with an exemplary embodiment.

FIG. 12 is a front perspective, exploded view of a portion of the connector assembly showing the cable connectors and the connector holder in accordance with an exemplary embodiment.

FIG. 13 is a front perspective, exploded view of a portion of the connector assembly showing the mounting assembly in accordance with an exemplary embodiment.

### DETAILED DESCRIPTION OF THE INVENTION

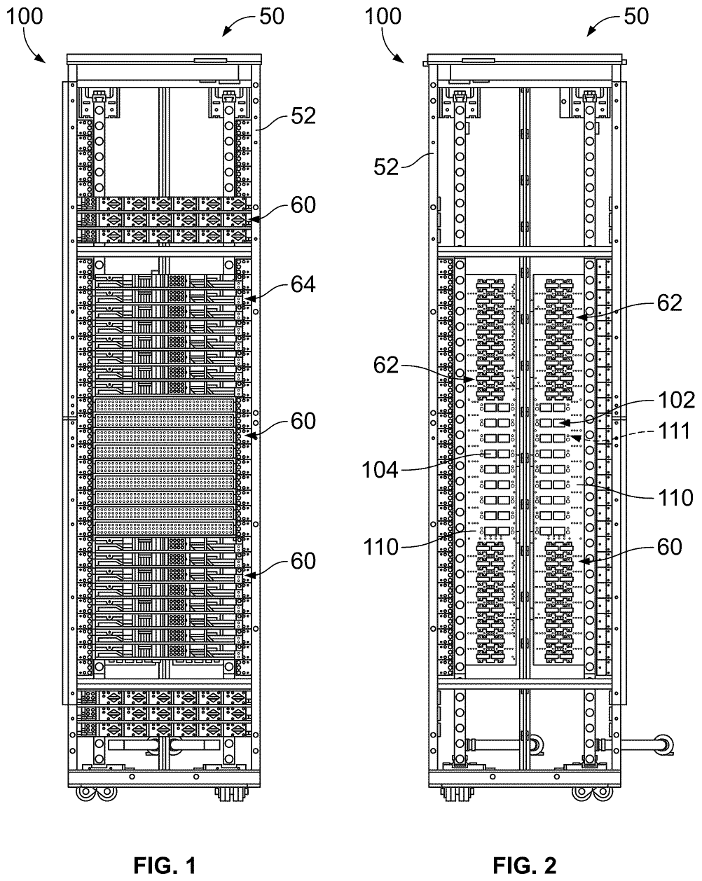

FIG. 1 is a front view of a communication system 100 in accordance with an exemplary embodiment. FIG. 2 is a front view of a portion of the communication system 100 in accordance with an exemplary embodiment. In an exemplary embodiment, the communication system 100 includes a chassis or rack 50 having a rack frame 52 holding electrical components 60. The rack 50 may be a server rack. The electrical components 60 may include fixed modules 62 (FIG. 2) and/or removable modules 64 (FIG. 1). The removable modules 64 may be mated to the fixed modules 62. For example, the removable modules 64 may be plugged into the rack frame 52 and removable from the rack frame 52. In various embodiments, the electrical components 60 may include one or more patch panels, switches, servers, routers, firewalls, and the like. The rack frame 52 may hold a power supply, cooling components, and the like.

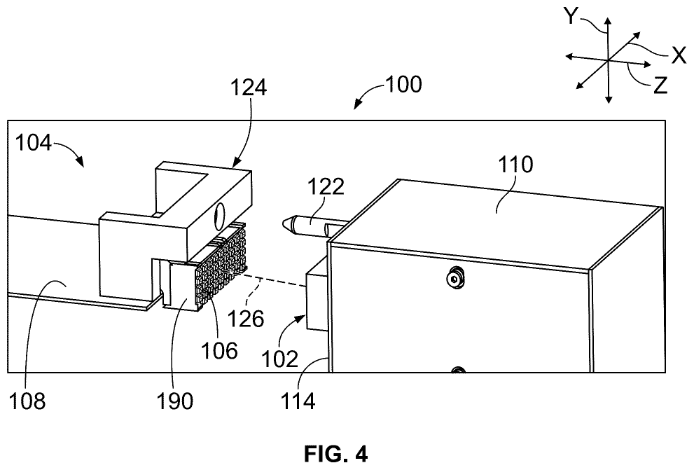

In an exemplary embodiment, the communication system 100 includes at least one connector assembly 102 (FIG. 2) and at least one mating connector assembly 104 (FIG. 4) configured to be mated with the corresponding at least one connector assembly 102. The connector assembly 102 may be part of one of the electrical components 60, such as one of the fixed modules 62. The mating connector assembly 104 may be part of one of the electrical components 60, such as one of the removable modules 64. In various embodiments, each mating connector assembly 104 may include one or more mating electrical connectors mounted to a circuit board, such as a backplane, a daughter card, a network switch, and the like.

In an exemplary embodiment, the communication system 100 includes a cabinet or cartridge 110 that holds the connector assemblies 102. The connector assemblies 102 may be cable connector assemblies having cables extending from corresponding cable connectors. The cartridge 110 may form part of the fixed modules 62. Optionally, multiple cartridges 110 may be provided (for example, left side and right side). The cartridge 110 may be coupled to the rack frame 52, such as at the rear of the rack frame 52. The cartridge 110 forms an enclosed space or chamber 111 for the connector assemblies 102 and the cables of the connector assemblies 102. The cartridge 110 is used for cable management. For example, the cables may be routed within the enclosed chamber 111 formed by the cartridge 110 to electrically connect between the various connector assemblies 102. The cartridge 110 is used to support or position the connector assemblies 102 for mating with the mating connector assemblies 104.

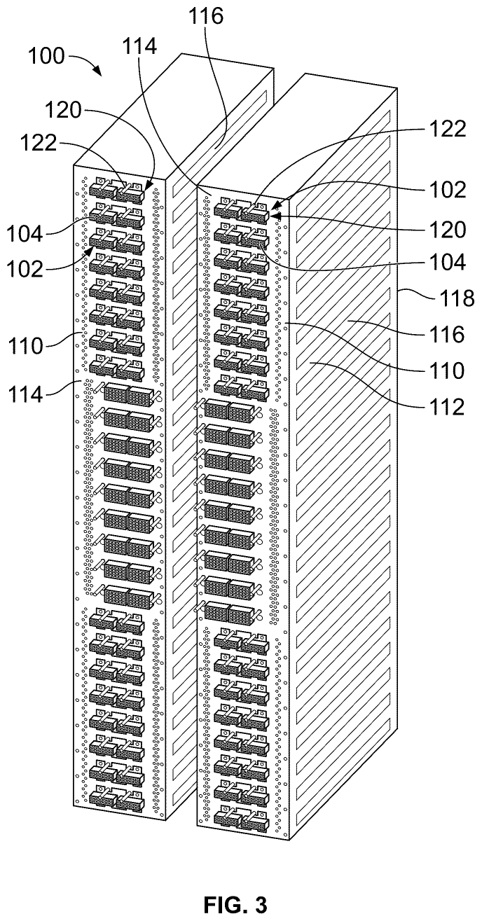

FIG. 3 illustrates a portion of the communication system 100 showing two of the cartridges 110 in accordance with an exemplary embodiment. Each cartridge 110 holds a plurality of the connector assemblies 102, such as in one or more rows and one or more columns. The connector assemblies 102 are provided at the front of the cartridge 110 for interfacing with the mating connector assemblies 104 (shown in FIG. 4).

In an exemplary embodiment, the cartridge 110 is formed from a plurality of panels 112, such as sheet metal panels. The cartridge 110 includes a front panel 114, side panels 116, and a rear panel 118. The panels 112 may additionally include an upper panel and/or a lower panel. The connector assemblies 102 are provided at the front panel 114 for mating with the mating connector assemblies 104. In an exemplary embodiment, the connector assemblies 102 are arranged in a column along the front panel 114. Optionally, the connector assemblies 102 may be provided in multiple columns. The mating ends of the connector assemblies 102 are external to the cartridge 110. For example, the connector assemblies 102 pass through ports or openings 120 in the front panel 114. The connector assemblies 102 are coupled to the front panel 114 adjacent the openings 120. In an exemplary embodiment, the connector assemblies 102 may float or move relative to the front panel 114 to align with and mate to the mating connector assemblies 104. In an exemplary embodiment, the connector assemblies 102 include mating guides, such as guideposts 122, to guide mating of the mating electrical connectors 104 with the connector assemblies 102. The guideposts 122 extend forward of the front panel 114.

FIG. 4 is a perspective view of a portion of the communication system 100 showing one of the mating connector assemblies 104 poised for coupling to the corresponding connector assembly 102. The connector assembly 102 is coupled to the cartridge 110, such as to the front panel 114. In the illustrated embodiment, the mating connector assembly 104 is a network component. For example, the mating connector assembly 104 may be a compute node, a memory module, a network switch, a storage device, a network accelerator, or another type of communication component. The mating connector assembly 104 may be a backplane component or a daughtercard component.

In an exemplary embodiment, the mating connector assembly 104 includes a mating electrical connector 106 mounted to a circuit board 108. The mating connector assembly 104 may be mounted to a front edge of the circuit board 108. The mating electrical connector 106 includes a connector housing 190 holding signal contacts (not shown). The signal contacts are terminated to the circuit board 108. The signal contacts may be socket contacts. The mating electrical connector 106 may include shields providing shielding for the signal contacts.

The connector assembly 102 is received in the cartridge 110. The connector assembly 102 is provided at the front panel 114 for mating with the mating connector assembly 104 along a mating axis 126. In the illustrated embodiment, the mating axis 126 extends along the Z-axis. The connector assemblies 102, 104 are configured to transmit and/or receive data through an interface. The connector assemblies 102 may includes receptacle connectors and the mating connector assemblies 104 may include plug connectors. In an exemplary embodiment, the guidepost 122 is configured to be mated with a guide module 124 of the mating connector assembly 104 to guide mating of the mating connector assembly 104 with the connector assembly 102. In the illustrated embodiment, the guide module 124 includes an opening that receives the guidepost 122. The mating guides may be used to align the connectors in one or more lateral directions transverse to the mating axis 126, such as along the X-axis and/or the Y-axis. In various embodiments, the mating guides may provide both horizontal alignment (X-axis) and vertical alignment (Y-axis).

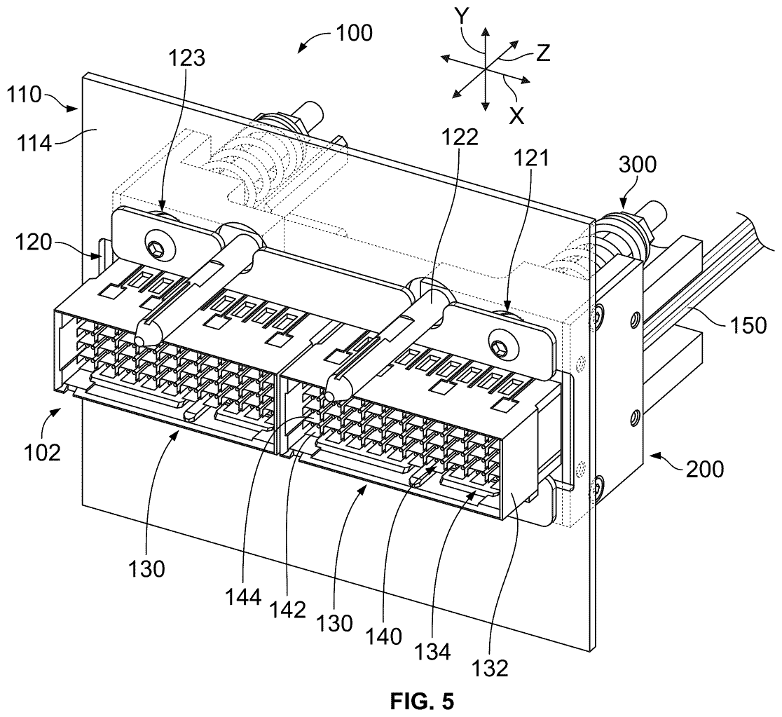

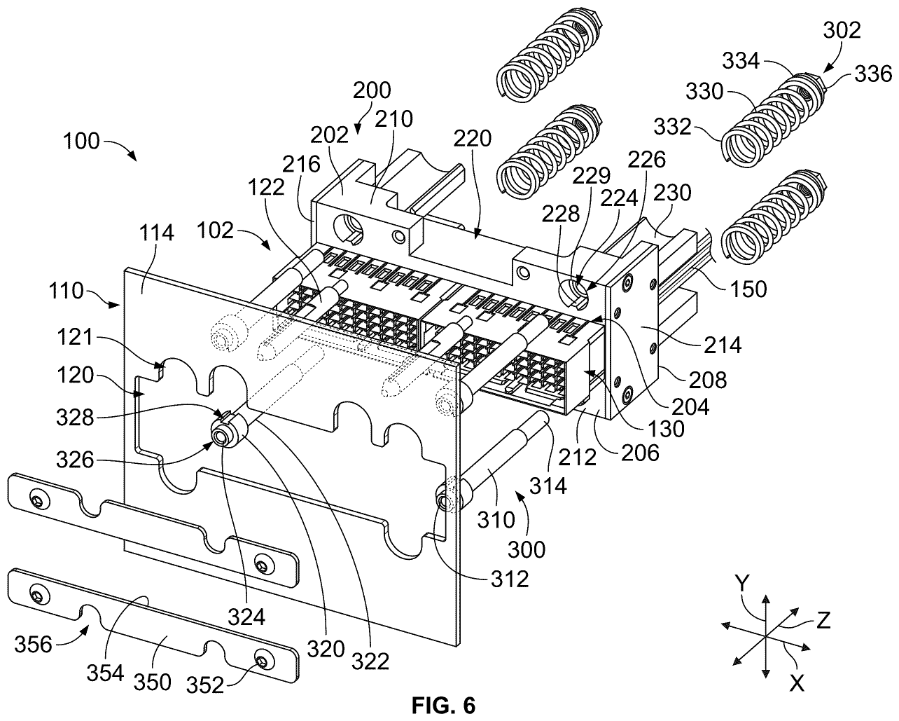

FIG. 5 is a front perspective view of a portion of the communication system 100 showing one of the connector assemblies 102 in accordance with an exemplary embodiment coupled to the front panel 114 of the cartridge 110. FIG. 6 is a front perspective, exploded view of the connector assembly 102 in accordance with an exemplary embodiment. The connector assembly 102 includes one or more cable connectors 130, a connector holder 200 holding the cable connector(s) 130, and a mounting assembly 300 for mounting the connector holder 200 and the cable connector(s) 130 to the front panel 114 of the cartridge 110.

In the illustrated embodiment, the connector assembly 102 includes two cable connectors 130 arranged side-by-side. However, greater or fewer cable connectors 130 may be provided in alternative embodiments. The cable connectors 130 may be vertically stacked rather than horizontally stacked in alternative embodiments. The mating ends of the cable connectors 130 pass through the opening 120 in the front panel 114 for mating with the mating electrical connector 106 (FIG. 4).

Each cable connector 130 includes a connector housing 132 holding contact assemblies 140. The connector housing 132 includes a cavity 134 that receives the mating end of the mating electrical connector 106. The contact assemblies 140 are arranged in the cavity 134, such as in rows and columns. The walls of the connector housing 132 may be chamfered and have a lead-in surfaces to guide mating of the mating electrical connector 106 in the cavity 134. The connector housing 132 may have guide features to properly position the mating electrical connector 106 within the cavity 134.

Each contact assembly 140 includes at least one signal contact 142, which is configured to be electrically connected to a wire or conductor of the corresponding cable 150 extending from the cable connector 130. In the illustrated embodiment, each contact assembly 140 includes a pair of the signal contacts 142, which define a differential pair. In various embodiments, the signal contacts 142 may be pin contacts. However, in alternative embodiments, the signal contacts 142 may be socket contacts, spring beam contacts, or other types of contacts. The signal contacts 142 may be stamped and formed contacts. Each contact assembly 140 includes a shield 144 provide electrical shielding for the signal contacts 142. The shield 144 is configured to be electrically connected to the wire shield of the wire and/or the cable shield of the cable. In the illustrated embodiment, the shield 144 is C-shaped providing electrical shielding on three sides of the pair of signal contacts 142. The shield 144 may have other shapes in alternative embodiments. The shield 144 may be a stamped and formed shield.

The connector holder 200 is used to hold the cable connector(s) 130 relative to the front panel 114. The connector holder 200 is configured to be coupled to the cartridge 110, via the mounting assembly 300, to position each cable connector 130 relative to the cartridge 110. In an exemplary embodiment, the cable connector 130 is movable relative to the connector holder 200 to position the cable connector 130 during mating with the mating electrical connector 106 (FIG. 4). For example, the connector holder 200 and the cable connector 130 may be movable along the mating axis 126 (along the Z-axis) to accommodate overtravel of the mating connector assembly 104 during mating. In various embodiments, the connector holder 200 and the cable connector 130 may have a limited amount of floating movement relative to the front panel 114 to accommodate misalignment of the cable connector 130 relative to the mating electrical connector 106. For example, the mounting assembly 300 allows movement of the connector holder 200 and the cable connector 130 relative to the front panel 114 along the X-axis and/or along the Y-axis to accommodate misalignment of the cable connector 130 relative to the mating electrical connector 106. The mounting assembly 300 may limit or confine the amount of floating movement in the lateral floating directions X/Y. For example, the mounting assembly 300 may limit floating movement, such as to approximately 5.0 mm for mating tolerance. In various embodiments, the mounting assembly 300 may limit floating movement to approximately 3.0 mm for mating tolerance.

The connector holder 200 includes a frame 202 defining a connector chamber 204. The cable connector(s) 130 are received in the connector chamber 204. The frame 202 supports the cable connector 130 in the connector chamber 204. The frame 202 extends between a front 206 and a rear 208 of the connector holder 200. The mating ends of each cable connector 130 is provided at or forward of the front 206 of the connector holder 200 for mating with the mating electrical connector 106. The cables 150 extends from the rear 208 of the connector holder 200. The guideposts 122 extend forward from the front 206, such as above the cable connector 130. Other locations are possible in alternative embodiments, such as the bottom for one or both sides of the frame 202.

In an exemplary embodiment, the frame 202 includes an upper frame member 210, a lower frame member 212, a first side frame member 214, and a second side frame member 216. The connector chamber 204 is defined between the upper frame member 210 and the lower frame member 212. The connector chamber 204 is defined between the first and second side frame members 214, 216. The upper frame member 210, the lower frame member 212, the first side frame member 214, and/or the second side frame member 216 may be plates or blocks. For example, the upper frame member 210, the lower frame member 212, the first side frame member 214, and/or the second side frame member 216 may be stamped and formed plates. The upper frame member 210, the lower frame member 212, the first side frame member 214, and/or the second side frame member 216 may be die cast or molded blocks. In an exemplary embodiment, the upper frame member 210, the lower frame member 212, the first side frame member 214, and/or the second side frame member 216 may be discrete pieces secured together using fasteners, clips, latches, welding or other securing means. In other various embodiments, the upper frame member 210, the lower frame member 212, the first side frame member 214, and/or the second side frame member 216 may be integral with each other. The upper frame member 210, the lower frame member 212, the first side frame member 214, and the second side frame member 216 form a brick 220 used to hold the cable connector 130. The brick 220 is a rectangular structure that surrounds the connector chamber 204. The brick 220 is configured to be coupled to the cartridge 110 to hold the cable connector 130 relative to the cartridge 110.

In an exemplary embodiment, the frame 202 includes mounting features 224 configured to be coupled to the mounting assembly 300. In the illustrated embodiment, the mounting features 224 include openings 226 in the frame members, such as in the upper frame member 210 and/or the lower frame member 212. In the illustrated embodiment, four openings 226 are provided near the four corners of the brick 220. In an exemplary embodiment, the mounting features 224 include keying features 228 for keyed mating with the mounting assembly 300. For example, the keying features 228 may be ribs, tabs or other types of protrusions extending into the openings 226. In other embodiments, the keying features 228 may be grooves, slots or other types of openings.

In an exemplary embodiment, the frame 202 includes support walls 230 extending from the rear 208. The support walls 230 may support portions of the mounting assembly 300. The support walls 230 may be aligned with the mounting features 224. In the illustrated embodiment, four support walls 230 are provided near the four corners of the brick 220. The support walls 230 may be used to separate or isolate the mounting assembly 300 from the cables 150, such as to prevent damage to the cables and/or prevent obstruction of operation of the mounting assembly 300.

In an exemplary embodiment, the mounting assembly 300 is operably coupled between the connector holder 200 and the front panel 114. The mounting assembly 300 allows the connector holder 200, and thus the cable connector(s) 130 to move relative to the front panel 114. For example, the mounting assembly 300 allows the connector holder 200 and the cable connector 130 to move along the mating axis 126 (Z-direction), such as to accommodate overtravel of the mating connector assembly 104 during mating. The mounting assembly 300 allows the connector holder 200 and the cable connector 130 to move in one or more lateral floating directions perpendicular to the mating direction, such as in a horizontal floating direction (X-axis) and/or a vertical floating direction (Y-axis).

In an exemplary embodiment, the mounting assembly 300 includes one or more locating assemblies 302 configured to interface with the connector holder 200 at the corresponding mounting features 224. Each locating assembly 302 of the mounting assembly 300 includes a shaft 310, a biasing member 330 operably coupled between the connector holder 200 and the shaft 310, and a support element 350 configured to be operably coupled between the shaft 310 and the front panel 114 of the cartridge 110 to support the shaft 310 relative to the front panel 114.

The support element 350 may be a front support configured to be coupled to the front panel 114 of the cartridge 110. The support element 350 is coupled to the shaft(s) 310, such as using fasteners 352, clips, latches, welding, or other securing means. In an exemplary embodiment, the support element 350 includes an inner surface 354 configured to be coupled to the front surface of the panel 114. In an exemplary embodiment, the support element 350 includes an elongated plate, such as extending along the top and/or bottom and/or sides of the opening 120. The support element 350 may be planar. The support element 350 may be coupled to multiple shafts 310. The support element 350 may include notches 356 that receive the guideposts 122. The support element 350 may have other shapes in alternative embodiments. For example, the support element 350 may be circular and configured to mate to a single shaft 310.

The shaft 310 is configured to be coupled to the support element 350. For example, the shaft 310 is configured to extend through a corresponding locating opening 121 in the front panel 114 to interface with the support element 350. The front panel 114 may be captured between the support element 350 and the shaft 310. The locating opening 121 may be at or near the port 120 in the front panel 114, such as being open to the port 120. In an exemplary embodiment, the shaft 310 is undersized relative to the locating opening 121 to allow a limited amount of floating movement in the locating opening 121 in a float direction (X-direction and/or Y-direction) perpendicular to the mating direction (Z direction) to allow the connector holder 200 and the cable connector 130 to move relative to the panel 114. In an exemplary embodiment, the biasing member 330 forward biases the connector holder 200 and the cable connector 130, such as to press the connector holder 200 toward the rear side of the panel 114. The biasing member 330 is compressible in a rearward compression direction parallel to the mating direction (for example, along the Z axis) to allow the connector holder 200 and the cable connector 130 to move rearward relative to the panel 114. As such, the mounting assembly 300 allows floating movement of the connector holder 200, and thus the cable connector(s) 130, in X/Y/Z directions to align the cable connectors 130 with the mating connectors 106 (FIG. 4) during the mating process.

The shaft 310 extends between a first end 312 and a second end 314. The first end 312 is at a front and configured to be coupled to the support element 350. The second end 314 is at a rear and configured to be coupled to the biasing member 330. The shaft 310 may be generally cylindrical. In an exemplary embodiment, the shaft 310 includes a head 320 and a stem 322 extending from the head 320 to the second end 314. The stem 322 may be threaded. The head 320 has a larger diameter than the diameter of the stem 322. In an exemplary embodiment, the shaft 310 includes a boss 324 extending from the head 320 opposite the stem 322. The boss 324 is at the first end 312. The boss 324 may be cylindrical. The boss 324 has a smaller diameter than the head 320. In an exemplary embodiment, the boss 324 is configured to pass through the locating opening 121 to interface with the support element 350. The support element 350 may be coupled to the boss 324 by the fastener 352. For example, the boss 324 may include a threaded bore 326 that receives the fastener 352.

The shaft 310 is configured to be coupled to the frame 202. For example, the shaft 310 is received in the corresponding opening 226 in the frame 202. For example, the stem 322 may pass through the opening 226 to the rear 208, such as along the support wall 230. The head 320 may be received in the opening 226. In an exemplary embodiment, the head 320 includes a keying feature 328. The keying feature 328 is configured to interface with the keying feature 228. In the illustrated embodiment, the keying feature is a slot or groove formed along the exterior of the head 320 that receives the rib defining the keying feature 228. The keying features 228, 328 may prevent rotation of the shaft 310 relative to the frame 202. In an exemplary embodiment, the head 320 may bottom out against a shoulder 229 in the opening 226 to position the shaft 310 relative to the frame 202. The biasing member 330 may forward bias the shoulder 229 against the rear side of the head 320.

The biasing member 330 is configured to be coupled to the corresponding shaft 310. For example, the stem 322 may pass through the biasing member 330. In the illustrated embodiment, the biasing member 330 is a compression spring, such as a coil spring. However, other types of biasing members may be used in alternative embodiments. The biasing member 330 may include other types of springs, such as a leaf spring, a Belleville spring, a wave spring, a torsion spring. The biasing member 330 may include another type of compression element, such as a foam compression member, a rubber compression member, and the like.

The biasing member 330 extends between a first end 332 and a second end 334. The first end 332 is configured to engage the frame 202, such as at or near the rear 208 of the frame 202. The first end 332 may be received in a pocket at the rear 208 to position and hold the first end 332. In an exemplary embodiment, a nut 336 is provided at the second end 334. The nut 336 may be threadably coupled to the shaft 310, such as to the threaded end of the stem 322, to secure the biasing member 330 to the shaft 310. For example, the shaft 310 may pass through the biasing member 330 to interface with the nut 336. The biasing member 330 directly engages the frame 202 to forward bias the connector holder 200 and the cable connector 130. For example, the biasing member 330 presses forward against the nut 336 to forward bias the connector holder 200 and the cable connector 130 in a forward position for mating with the mating electrical connector 106. Other securing means may be provided in alternative embodiments. The biasing member 330 and the nut 336 may be received in a trough or cradle in the support wall 230.

In an exemplary embodiment, the frame 202 is configured to slide rearward along the stems 322 of the shafts 310. For example, the biasing member 330 is compressible to allow the connector holder 200 and the cable connector(s) 130 to move in the rearward compression direction (Z direction). The shaft 310 guides movement of the frame 202 in the rearward compression direction. For example, the shafts 310 may limit or restrict movement of the frame 202 to movement parallel to the mating axis (Z-direction).

In an exemplary embodiment, the locating openings 121 are used to control floating movement of the connector assembly 102, such as in the lateral floating direction(s) (for example, X direction and/or Y direction). In an exemplary embodiment, each locating opening 121 is oversized relative to the shaft 310, such as being oversized relative to the boss 324, which is received in the locating opening 121. For example, clearance gaps 123 may be provided around the boss 324 to allow the boss 324 to move or float laterally within the locating opening 121. In an exemplary embodiment, the locating opening 121 is horizontally oversized relative to the boss 324 allowing the boss 324 to move side-to-side within the locating opening 121 to allow a limited amount of lateral floating movement of the connector holder 200 and the cable connector(s) 130 relative to the front panel 114. As such, the connector housing 132 is movable in the X-direction (for example, side-to-side) relative to the panel 114. The amount of lateral movement may be limited to a confined amount by the edges of the panel defining the locating opening 121. The clearance gap in the side-to-side direction may be approximately 3.0 mm in various embodiments. In an exemplary embodiment, the locating opening 121 is vertically oversized relative to the boss 324 allowing the boss 324 to move up-and-down within the locating opening 121 to allow a limited amount of lateral floating movement of the connector holder 200 and the cable connector(s) 130 relative to the front panel 114. As such, the connector housing 132 is movable in the Y-direction (for example, up and down) relative to the panel 114. The amount of lateral movement may be limited to a confined amount by the edges of the panel 114 defining the locating opening 121. The clearance gap in the up-and-down direction may be approximately 3.0 mm in various embodiments.

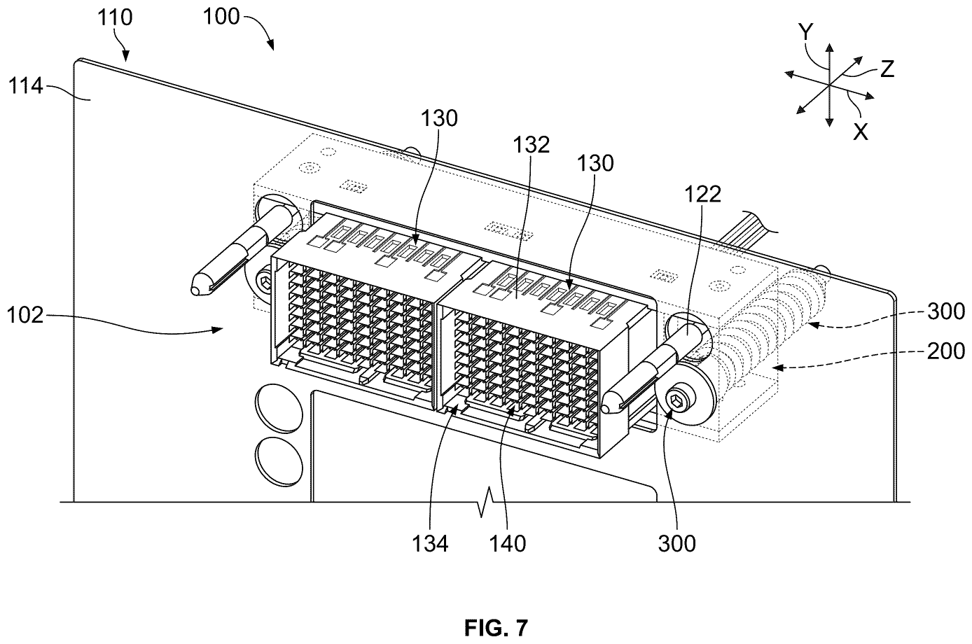

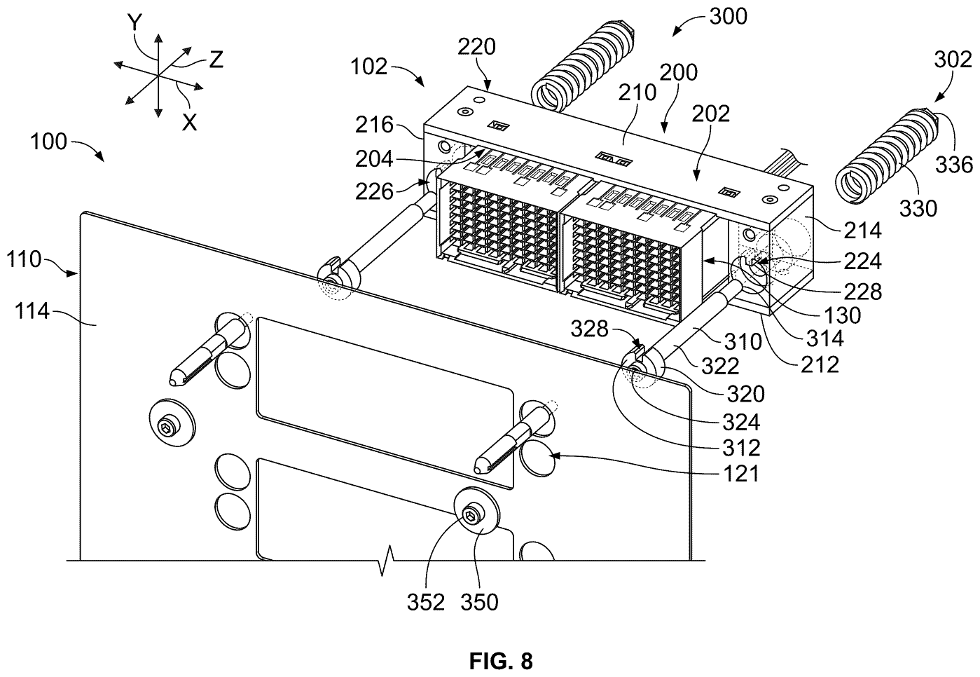

FIG. 7 is a front perspective view of a portion of the communication system 100 showing one of the connector assemblies 102 in accordance with an exemplary embodiment coupled to the front panel 114 of the cartridge 110. FIG. 8 is a front perspective, exploded view of the connector assembly 102 in accordance with an exemplary embodiment. The size and shapes of the components of the connector assembly 102 may be different than the embodiment shown in FIGS. 5 and 6. The connector assembly 102 includes one or more of the cable connectors 130, the connector holder 200 holding the cable connector(s) 130, and the mounting assembly 300 for mounting the connector holder 200 and the cable connector(s) 130 to the front panel 114 of the cartridge 110.

In the illustrated embodiment, the connector assembly 102 includes two of the cable connectors 130 arranged side-by-side. However, greater or fewer cable connectors 130 may be provided in alternative embodiments. The cable connector 130 includes the connector housing 132 holding the contact assemblies 140 in the cavity 134. In the illustrated embodiment, a different number of rows and/or columns of the contact assemblies 140 are provided.

The connector holder 200 is sized and shaped differently to accommodate the different size/shape cable connector(s) 130. The connector holder 200 is configured to be coupled to the cartridge 110, via the mounting assembly 300, to position each cable connector 130 relative to the cartridge 110. In an exemplary embodiment, the cable connector 130 is movable relative to the connector holder 200 to position the cable connector 130 during mating with the mating electrical connector 106 (FIG. 4). For example, the connector holder 200 and the cable connector 130 may be movable along the mating axis 126 (along the Z-axis) to accommodate overtravel of the mating connector assembly 104 during mating. In various embodiments, the connector holder 200 and the cable connector 130 may have a limited amount of floating movement relative to the front panel 114 to accommodate misalignment of the cable connector 130 relative to the mating electrical connector 106. For example, the mounting assembly 300 allows movement of the connector holder 200 and the cable connector 130 relative to the front panel 114 along the X-axis and/or along the Y-axis to accommodate misalignment of the cable connector 130 relative to the mating electrical connector 106. The mounting assembly 300 may limit or confine the amount of floating movement in the lateral floating directions X/Y. For example, the mounting assembly 300 may limit floating movement, such as to approximately 5.0 mm for mating tolerance. In various embodiments, the mounting assembly 300 may limit floating movement to approximately 3.0 mm for mating tolerance.

The connector holder 200 includes the frame 202 and the cable connector(s) 130 are received in the connector chamber 204 of the frame. In an exemplary embodiment, the frame 202 includes the upper frame member 210, the lower frame member 212, the first side frame member 214, and the second side frame member 216. The upper frame member 210, the lower frame member 212, the first side frame member 214, and/or the second side frame member 216 may be plates or blocks. The upper frame member 210, the lower frame member 212, the first side frame member 214, and the second side frame member 216 form the brick 220 used to hold the cable connector(s) 130. The brick 220 is configured to be coupled to the cartridge 110 to hold the cable connector 130 relative to the cartridge 110. In the illustrated embodiment, the mounting features 224 include openings 226 in the first side frame member 214 and/or the second side frame member 216. In the illustrated embodiment, two openings 226 are provided along the sides of the brick 220. The guideposts 122 extend forward from the frame 202, such as from the first side frame member 214 and/or the second side frame member 216. The guideposts 122 pass through openings in the front panel 114.

The mounting assembly 300 includes the locating assemblies 302 configured to interface with the connector holder 200 at the corresponding mounting features 224. The mounting assembly 300 is operably coupled between the connector holder 200 and the front panel 114. The mounting assembly 300 allows the connector holder 200, and thus the cable connector(s) 130, to move relative to the front panel 114. For example, the mounting assembly 300 allows the connector holder 200 and the cable connector 130 to move along the mating axis 126 (Z-direction), such as to accommodate overtravel of the mating connector assembly 104 during mating. The mounting assembly 300 allows the connector holder 200 and the cable connector 130 to move in one or more lateral floating directions perpendicular to the mating direction, such as in a horizontal floating direction (X-axis) and/or a vertical floating direction (Y-axis).

Each locating assembly 302 includes the shaft 310, the biasing member 330 operably coupled between the connector holder 200 and the shaft 310, and the support element 350 configured to be operably coupled between the shaft 310 and the front panel 114 of the cartridge 110 to support the shaft 310 relative to the front panel 114. The support elements 350 may be sized and shaped differently than the embodiment shown in FIGS. 5 and 6. For example, the support elements 350 are circular, such as being washers configured to be coupled to the front surface of the front panel 114 to secure the mounting assembly 300 to the front panel 114.

The shaft 310 includes the head 320 at the first end 312 and the stem 322 at the second end 314. The stem 322 is configured to be threadably coupled to the nut 336 to secure the biasing member 330 to the shaft 310. The shaft 310 is configured to be coupled to the support element 350. For example, the shaft 310 is configured to extend through a corresponding locating opening 121 in the front panel 114 to interface with the support element 350. The front panel 114 may be captured between the support element 350 and the shaft 310. The boss 324 at the front of the shaft is configured to pass through the locating opening 121 and the support element 350 is coupled to the boss 324 by the fastener 352. The boss 324 of the shaft 310 is undersized relative to the locating opening 121 to allow a limited amount of floating movement in the locating opening 121 in a float direction (X-direction and/or Y-direction) perpendicular to the mating direction (Z direction) to allow the connector holder 200 and the cable connector 130 to move relative to the panel 114. The biasing member 330 forward biases the connector holder 200 and the cable connector 130, such as to press the connector holder 200 toward the rear side of the panel 114. The biasing member 330 is compressible in a rearward compression direction parallel to the mating direction (for example, along the Z axis) to allow the connector holder 200 and the cable connector 130 to move rearward relative to the panel 114. As such, the mounting assembly 300 allows floating movement of the connector holder 200, and thus the cable connector(s) 130, in X/Y/Z directions to align the cable connectors 130 with the mating connectors 106 (FIG. 4) during the mating process.

When assembled, the shaft 310 is coupled to the frame 202 by loading the stem 322 of the shaft 310 in the corresponding opening 226 in the frame 202. The head 320 is received in the opening 226 and the keying feature 328 interfaces with the keying feature 228 in the opening 226. The stem 322 of the shaft passes through the biasing member 330 and is secured using the nut 336. The biasing member 330 is captured between the frame 202 and the nut 336. The biasing member 330 directly engages the frame 202 to forward bias the connector holder 200 and the cable connector 130 in a forward position for mating with the mating electrical connector 106. In an exemplary embodiment, the frame 202 is configured to slide rearward along the stems 322 of the shafts 310 during mating with the mating connector 106. The shaft 310 guides movement of the frame 202 in the rearward compression direction.

In an exemplary embodiment, the locating openings 121 are used to control floating movement of the connector assembly 102, such as in the lateral floating direction(s) (for example, X direction and/or Y direction). In an exemplary embodiment, each locating opening 121 is oversized relative to the shaft 310, such as being oversized relative to the boss 324, which is received in the locating opening 121. For example, the clearance gaps 123 are provided around the boss 324 to allow the boss 324 to move or float laterally within the locating opening 121 in the X-direction (for example, side-to-side) and/or in the Y-direction (for example, up and down) relative to the panel 114. The amount of lateral movement may be limited to a confined amount by the edges of the panel 114 defining the locating opening 121. The clearance gaps 123 may be approximately 3.0 mm in various embodiments.

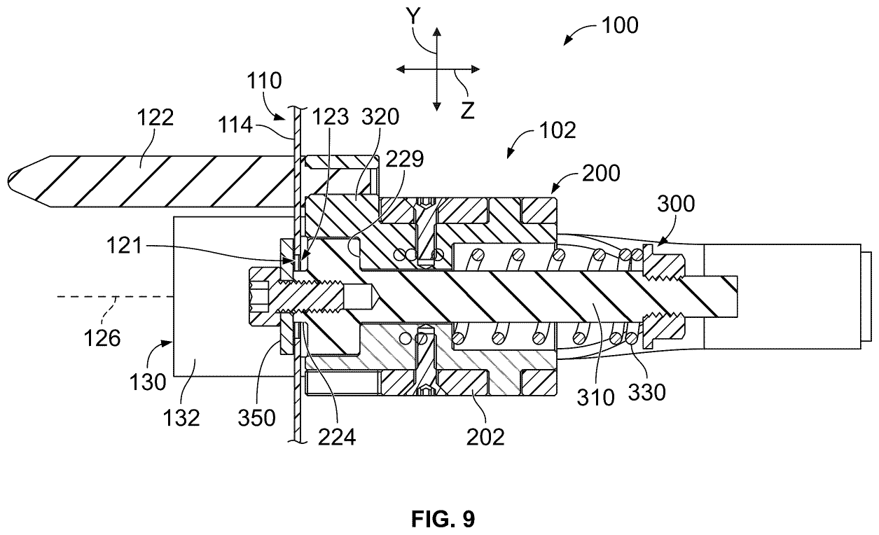

FIG. 9 is a cross-sectional view of a portion of the communication system 100 showing the connector assembly 102 mounted to the front panel 114 of the cartridge 110 in accordance with an exemplary embodiment. The cable connector 130 is held relative to the cartridge 110 by the connector holder 200. The connector holder 200 is held relative to the cartridge 110 by the mounting assembly 300. For example, the shaft 310 is coupled to the front panel 114 by the support element 350 and the shaft 310 is coupled to the connector holder 200 by the biasing member 330. The mating end of the cable connector 130 passes through the front panel 114 for mating with the mating electrical connector 106.

When assembled, the shaft 310 passes through the opening 226 in the frame 202. The head 320 bottoms out against the shoulder 229. The boss 324 protrudes forward of the head 320 and is configured to interface with the support element 350. The boss 324 passes through the locating opening 121 in the front panel 114 to interface with the support element 350. In an exemplary embodiment, the boss 324 holds the support element 350 at a spaced apart location such that a clearance gap is provided between the head 320 and the support element 350 that receives the front panel 114. The clearance gap may be wider than the thickness of the front panel 114 to allow free movement of the mounting assembly 300 relative to the front panel 114 in the floating direction(s). For example, the mounting assembly 300 does not bind on the front panel 114, but rather is able to freely move in the X and Y directions within the clearance gap 123.

During mating, the guidepost 122, which protrudes forward of the panel 114 and the cable connector 130, is configured to interface with the mating connector assembly 104 (shown in FIG. 4). The guidepost 122 is used to generally align the mating connector assembly 104 with the cable connector 130. If the cable connector 130 is misaligned (for example, vertically offset or horizontally offset), the mounting assembly 300 allows floating movement of the connector holder 200, and thus the cable connector 130, to align with the mating connector assembly 104. For example, the connector holder 200 and the cable connector 130 are able to move in a floating direction, such as side-to-side (X direction) and/or up-and-down (Y direction), to accommodate the misalignment. During mating, the mating connector assembly 104 is plugged into the rack or chassis in a mating direction along the mating axis 126. The mating ends of the mating electrical connector 106 is plugged into the connector housing 132 to electrically connect the signal contacts and the shields with the mating electrical connector 106. Once fully mated, further loading of the mating connector assembly 104 in the mating direction causes compression of the mounting assembly 300. For example, the biasing members 330 are compressed allowing the frame 202 to move in a rearward compression direction to accommodate the overloading of the mating connector assembly 104.

The biasing members 330 are compressible in the rearward compression direction to allow the cable connector 130 to move to a rearward position, which prevents damage to the cable connector 130 and the mating electrical connector 106 during the mating process. In an exemplary embodiment, the biasing members 330 may be preloaded to a predetermined spring force. As such, the biasing members 330 are not compressed until the predetermined spring force is exceeded. The preload spring force may be greater than the mating force to fully mate the mating electrical connector 106 with the cable connector 130. For example, the mating force may be defined by the force required to mate the signal contacts and the shields. In various embodiments, the mating force may be less than 20 pounds. The preload spring force may be set at 20 pounds to allow mating of the signal contacts and the shields without rearward movement of the cable connector 130. The biasing members 330 compress only when the preload force is exceeded.

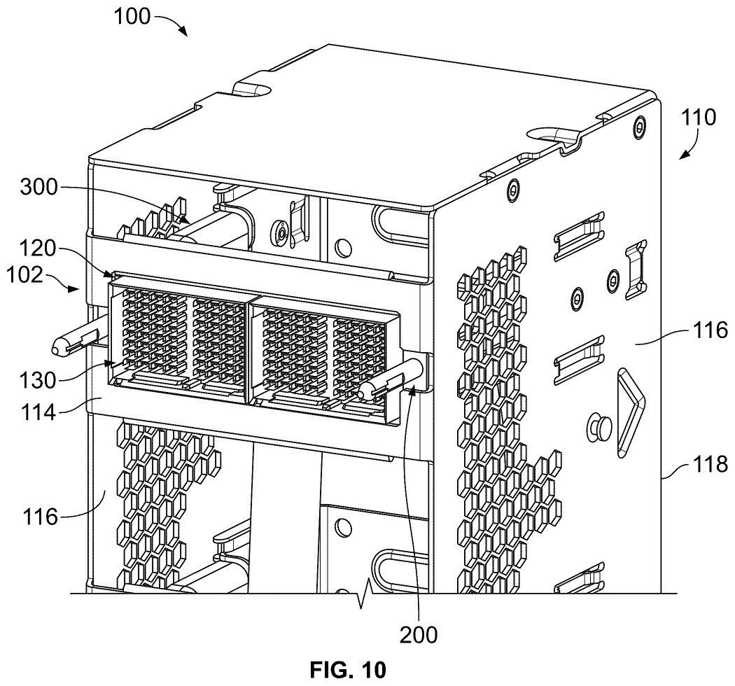

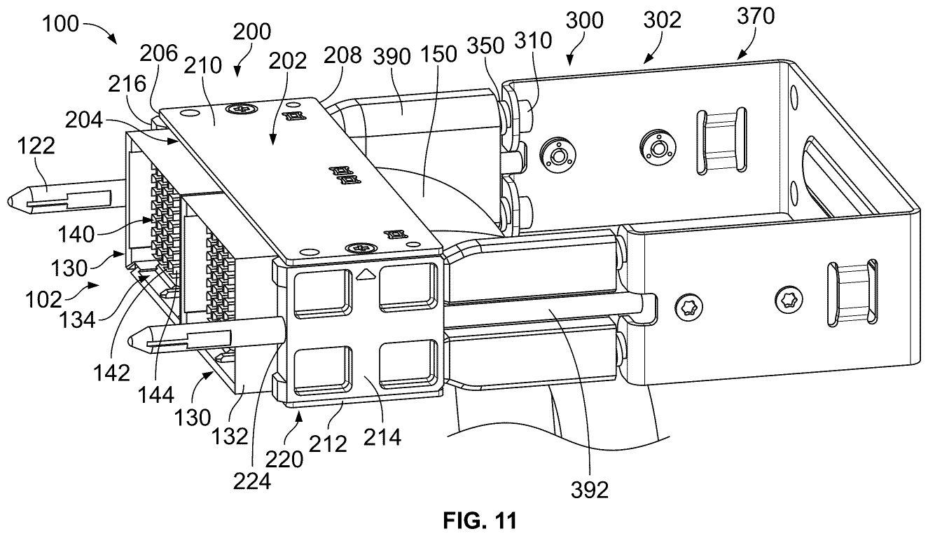

FIG. 10 is a perspective view of a portion of the communication system 100 showing one of the connector assemblies 102 in accordance with an exemplary embodiment. The connector assembly 102 is sized and shaped differently for mounting to the cartridge 110 at the side panels 116, and/or the rear panel 118 rather than the front panel 114. The mating end of the cable connector 130 passes through the opening 120 at the front panel 114, but the connector assembly 102 is supported by the side panels 116, and/or the rear panel 118 rather than the front panel 114.

The connector assembly 102 includes one or more of the cable connectors 130, the connector holder 200 holding the cable connector(s) 130, and the mounting assembly 300 for mounting the connector holder 200 and the cable connector(s) 130 to the front panel 114 of the cartridge 110. The mounting assembly 300 is configured to be mounted to the side panels 116 and/or the rear panel 118 rather than the front panel 114.

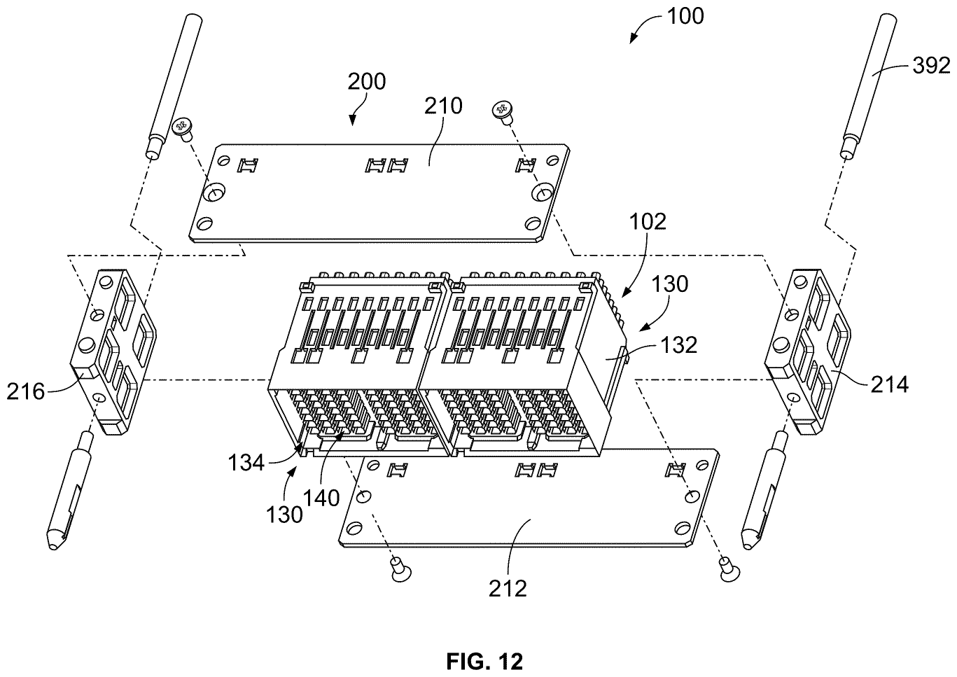

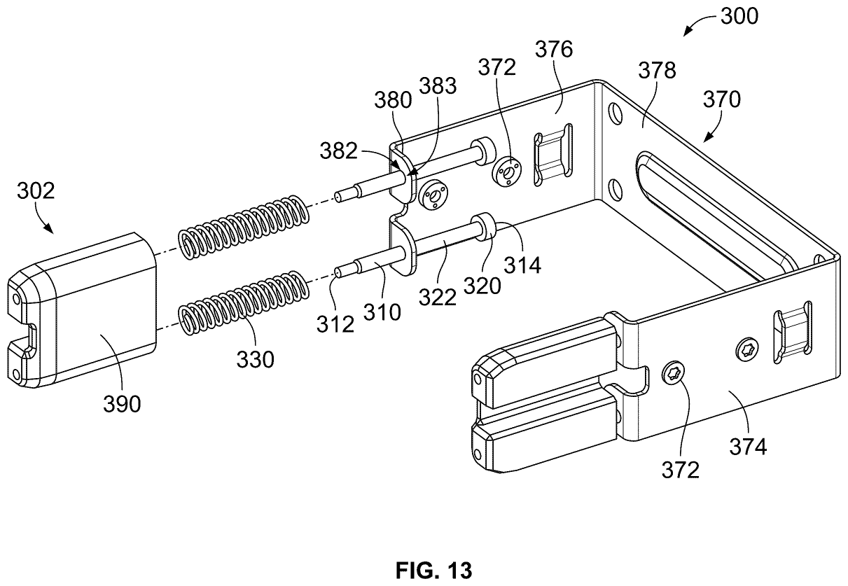

FIG. 11 is a front perspective view of a portion of the communication system 100 showing one of the connector assemblies 102 in accordance with an exemplary embodiment. FIG. 12 is a front perspective, exploded view of a portion of the connector assembly 102 showing the cable connectors 130 and the connector holder 200 in accordance with an exemplary embodiment. FIG. 13 is a front perspective, exploded view of a portion of the connector assembly 102 showing the mounting assembly 300 in accordance with an exemplary embodiment.

In the illustrated embodiment, the connector assembly 102 includes two cable connectors 130 arranged side-by-side. However, greater or fewer cable connectors 130 may be provided in alternative embodiments. Each cable connector 130 includes the connector housing 132 holding the contact assemblies 140 in the cavity 134. The contact assemblies 140 are arranged in a plurality of rows and columns. Each contact assembly 140 includes the signal contacts 142 electrically connected to the corresponding cable 150 and the shield 144 providing electrical shielding for the signal contacts 142.

The connector holder 200 is used to hold the cable connector(s) 130 relative to the cartridge 110. The connector holder 200 is configured to be coupled to the cartridge 110, via the mounting assembly 300, to position each cable connector 130 relative to the cartridge 110. In an exemplary embodiment, the cable connector 130 is movable relative to the connector holder 200 to position the cable connector 130 during mating with the mating electrical connector 106 (FIG. 4). For example, the connector holder 200 and the cable connector 130 may be movable along the mating axis 126 (along the Z-axis) to accommodate overtravel of the mating connector assembly 104 during mating. In various embodiments, the connector holder 200 and the cable connector 130 may have a limited amount of floating movement relative to the front panel 114 to accommodate misalignment of the cable connector 130 relative to the mating electrical connector 106. For example, the mounting assembly 300 allows movement of the connector holder 200 and the cable connector 130 relative to the cartridge 110 along the X-axis and/or along the Y-axis to accommodate misalignment of the cable connector 130 relative to the mating electrical connector 106. The mounting assembly 300 may limit or confine the amount of floating movement in the lateral floating directions X/Y. For example, the mounting assembly 300 may limit floating movement, such as to approximately 5.0 mm for mating tolerance. In various embodiments, the mounting assembly 300 may limit floating movement to approximately 3.0 mm for mating tolerance.

The connector holder 200 includes the frame 202 defining a connector chamber 204. The cable connector(s) 130 are received in the connector chamber 204. The frame 202 extends between the front 206 and the rear 208 of the connector holder 200. The guideposts 122 extend forward from the front 206, such as along the sides of the cable connectors 130. Other locations are possible in alternative embodiments, such as above and/or below the cable connectors 130.

In an exemplary embodiment, the frame 202 includes the upper frame member 210, the lower frame member 212, the first side frame member 214, and the second side frame member 216. The upper frame member 210, the lower frame member 212, the first side frame member 214, and/or the second side frame member 216 may be plates or blocks. The upper frame member 210, the lower frame member 212, the first side frame member 214, and the second side frame member 216 form the brick 220 used to hold the cable connector 130. The brick 220 is configured to be coupled to the cartridge 110 to hold the cable connector 130 relative to the cartridge 110.

In an exemplary embodiment, the mounting assembly 300 the locating assembly 302 configured to interface with the connector holder 200 at the corresponding mounting features 224. The locating assembly 302 includes the shafts 310, the biasing members 330 operably coupled between the connector holder 200 and the shafts 310, a support element 370 configured to be operably coupled between the shaft 310 and the cartridge 110 to support the shafts 310 relative to the cartridge 110, and sliders 390 operably coupled between the connector holder 200 and the support element 370.

The support element 370 may be a rear support configured to be coupled to the cartridge 110 at or near the rear panel 118. The support element 370 may be coupled to the side panels 116 and/or the rear panel 118. The support element 370 is configured to be coupled to the side panels 116 by fasteners 372. The support element 370 is coupled to the connector holder 200 through the shafts 310 and the biasing members 330. In an exemplary embodiment, the support element 370 includes side walls 374, 376 and an end wall 378 between the side walls 374, 376. For example, the support element 370 may be U-shaped. The end wall 378 is configured to extend along the rear panel 118. The side walls 374, 376 are configured to extend along the side panels 116. The support element 370 may have other shapes in alternative embodiments. In various embodiments, the support element 370 may be a multi-piece support, such as including the side walls 374, 376 without the end wall 378 therebetween.

Each shaft 310 is configured to be coupled to the connector holder 200 and the support element 370. For example, the shafts 310 may be coupled to support tabs 380 extending from the side walls 374, 376. The sliders 390 may be positioned between the support tabs 380 and the frame 202, such as the side frame members 214, 216. The shafts 310 may pass through locating openings 382 in the support tabs 380. The support tabs 380 and the locating openings 382 may be fixed relative to the panels of the cartridge 110; however, the shaft 310 may be movable relative to the support tabs 380 in the locating openings 382. The shaft 310 is thus movable relative to the cartridge 110 to allow alignment of the cable connector 130 with the mating connector assembly 104. In an exemplary embodiment, the shaft 310 is undersized relative to the locating openings 382 to allow a limited amount of floating movement in the locating openings 382 in a float direction (X-direction and/or Y-direction) perpendicular to the mating direction (Z direction) to allow the connector holder 200 and the cable connector 130 to move relative to the cartridge 110. In an exemplary embodiment, the biasing member 330 forward biases the connector holder 200 and the cable connector 130 relative to the support element 370. The biasing member 330 is compressible in a rearward compression direction parallel to the mating direction (for example, along the Z axis) to allow the connector holder 200 and the cable connector 130 to move rearward relative to the panel 114. As such, the mounting assembly 300 allows floating movement of the connector holder 200, and thus the cable connector(s) 130, in X/Y/Z directions to align the cable connectors 130 with the mating connectors 106 (FIG. 4) during the mating process.

The shaft 310 extends between a first end 312 and a second end 314. The first end 312 is at a front and configured to be coupled to the frame 202, such as to the side frame members 214, 216. The first end 312 may be threadably coupled to the frame 202. The second end 314 is at a rear and is configured to be coupled to the support element 370. The shaft 310 may be generally cylindrical. In an exemplary embodiment, the shaft 310 includes the head 320 and the stem 322 extending from the head 320 to the first end 312. The stem 322 is configured to pass through the corresponding slider 390. The stem 322 may pass through the locating openings 382 in the support tabs 380. The head 320 is configured to be coupled to the rear surface of the support tabs 380.

The biasing member 330 is configured to be coupled to the corresponding shaft 310. For example, the stem 322 may pass through the biasing member 330. The biasing members 330 are configured to be positioned between the sliders 390 and the support tabs 380. The ends of the biasing members 330 are received in pockets in the rear end of the sliders 390. The biasing member s330 directly engage the sliders 390 to forward bias the sliders 390 toward the frame 202. The sliders 390 may press the frame 202 in a forward biasing direction in a forward position for mating with the mating electrical connector 106.

In an exemplary embodiment, the sliders 390 and the shafts 310 may slide rearward relative to the support tabs 380 of the support element 370. For example, the biasing members 330 are compressible to allow the connector holder 200 and the cable connector(s) 130 to move in the rearward compression direction (Z direction). The shafts 310 guide movement of the frame 202 in the rearward compression direction. For example, the shafts 310 may limit or restrict movement of the frame 202 to movement parallel to the mating axis (Z-direction).

In an exemplary embodiment, the locating openings 382 are used to control floating movement of the connector assembly 102, such as in the lateral floating direction(s) (for example, X direction and/or Y direction). In an exemplary embodiment, each locating opening 382 is oversized relative to the shaft 310, such as being oversized relative to the stem 322, which is received in the locating opening 382. For example, clearance gaps 383 may be provided around the stem 322 to allow the stem 322 to move or float laterally within the locating opening 382. In an exemplary embodiment, the locating opening 382 is horizontally oversized relative to the stem 322 allowing the stem 322 to move side-to-side within the locating opening 382 to allow a limited amount of lateral floating movement of the connector holder 200 and the cable connector(s) 130 relative to the support element 370 and thus relative to the cartridge 110. As such, the connector housing 132 is movable in the X-direction (for example, side-to-side) relative to the cartridge 110. The amount of lateral movement may be limited to a confined amount by the edges defining the locating opening 382. The clearance gap in the side-to-side direction may be approximately 3.0 mm in various embodiments. In an exemplary embodiment, the locating opening 382 is vertically oversized relative to the stem 322 allowing the stem 322 to move up-and-down within the locating opening 382 to allow a limited amount of lateral floating movement of the connector holder 200 and the cable connector(s) 130 relative to the support element 370 and thus the cartridge 110. As such, the connector housing 132 is movable in the Y-direction (for example, up and down) relative to the cartridge 110. The amount of lateral movement may be limited to a confined amount by the edges defining the locating opening 382. The clearance gap in the up-and-down direction may be approximately 3.0 mm in various embodiments.

In an exemplary embodiment, an anti-rotation pin 392 extends along the slider 390 between the frame 202 and the support element 370. The anti-rotation pin 392 prevents rotation of the slide 390 during compression of the biasing member 330.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112(f), unless and until such claim limitations expressly use the phrase “means for” followed by a statement of function void of further structure.

What is claimed is:

1. A connector assembly comprising:
a connector holder having a frame defining a connector chamber, the frame extending between a front and a rear of the connector holder, the frame including an upper frame member, a lower frame member, and first and second side frame members extending between the upper and lower frame members to define the connector chamber;
a cable connector received in the connector chamber, the cable connector including a connector housing holding contact assemblies, each contact assembly including a signal contact and a cable terminated to the signal contact, the signal contact configured to be mated with a mating signal contact of a mating connector in a mating direction; and
a mounting assembly for mounting the connector holder to a panel, the mounting assembly including a shaft, a biasing member operably coupled between the connector holder and the shaft, and a support element configured to be operably coupled between the shaft and the panel to support the shaft relative to the panel, the shaft configured to be received in a locating opening, wherein the shaft is undersized relative to the locating opening to allow a limited amount of floating movement in the locating opening in a float direction perpendicular to the mating direction to allow the connector holder and the cable connector to move relative to the panel, the biasing member forward biasing the cable connector and being compressible in a rearward compression direction parallel to the mating direction to allow the connector holder and the cable connector to move rearward relative to the panel.

2. The connector assembly of claim 1, wherein the shaft holds the support element spaced apart from the front of the frame to form a clearance gap forward of the frame, the clearance gap configured to receive the front panel.

3. The connector assembly of claim 2, wherein the clearance gap is wider than a thickness of the front panel such that the frame is spaced apart from the front panel.

4. The connector assembly of claim 1, wherein the support element is secured to the shaft by a fastener.

5. The connector assembly of claim 1, wherein the shaft is configured to move in at least two lateral float directions in the locating opening.

6. The connector assembly of claim 1, wherein the shaft includes a head and a stem extending from the head, the head being received in the frame, the frame configured to slide along the stem as the biasing member is compressed.

7. The connector assembly of claim 6, wherein the shaft includes a boss extending forward from the head, the boss passing through the locating opening, the support element engaging the boss.

8. The connector assembly of claim 7, wherein the boss is movable in the locating opening in the float direction.

9. The connector assembly of claim 1, wherein the frame includes a pocket at the rear, the pocket receiving the biasing member.

10. The connector assembly of claim 1, wherein the frame includes a front opening and a shoulder extending into the front opening, the shaft received in the front opening and engaging the shoulder to position the shaft relative to the frame.

11. The connector assembly of claim 1, wherein the mounting assembly is coupled to at least one of the upper frame member and the lower frame member.

12. The connector assembly of claim 1, wherein the mounting assembly is coupled to at least one of the first side frame member and the second side frame member.

13. The connector assembly of claim 1, wherein the mounting assembly includes a second shaft, a second biasing member operably coupled between the connector holder and the second shaft, and a second support element configured to be operably coupled between the second shaft and the panel to support the second shaft relative to the panel, the second shaft configured to be received in a second locating opening in the panel, wherein the second shaft is undersized relative to the second locating opening to allow a limited amount of floating movement in the second locating opening in a float direction perpendicular to the mating direction, the second biasing member forward biasing the cable connector and being compressible in a rearward compression direction parallel to the mating direction.

14. The connector assembly of claim 1, further comprising a guide pin extending forward of the frame to guide mating with the mating connector.

15. The connector assembly of claim 1, wherein the support element includes a support tab, the locating opening provided in the support tab.

16. A connector assembly comprising:
a connector holder having a frame defining a connector chamber, the frame extending between a front and a rear of the connector holder, the frame including an upper frame member, a lower frame member, and first and second side frame members extending between the upper and lower frame members to define the connector chamber;
a first cable connector received in the connector chamber, the first cable connector including a first connector housing holding first contact assemblies, each first contact assembly including a first signal contact and a first cable terminated to the first signal contact, the first signal contact configured to be mated with a first mating signal contact of a first mating connector in a mating direction;
a second cable connector received in the connector chamber, the second cable connector including a second connector housing holding second contact assemblies, each second contact assembly including a second signal contact and a second cable terminated to the second signal contact, the second signal contact configured to be mated with a second mating signal contact of a second mating connector in a mating direction; and
a mounting assembly for mounting the connector holder to a panel, the mounting assembly including a shaft, a biasing member operably coupled between the connector holder and the shaft, and a support element configured to be operably coupled between the shaft and the panel to support the shaft relative to the panel, the shaft configured to be received in a locating opening, wherein the shaft is undersized relative to the locating opening to allow a limited amount of floating movement in the locating opening in a float direction perpendicular to the mating direction to allow the connector holder and the cable connector to move relative to the panel, the biasing member forward biasing the cable connector and being compressible in a rearward compression direction parallel to the mating direction to allow the connector holder and the cable connector to move rearward relative to the panel.

17. The connector assembly of claim 16, wherein the mounting assembly includes a second shaft, a second biasing member operably coupled between the connector holder and the second shaft, and a second support element configured to be operably coupled between the second shaft and the panel to support the second shaft relative to the panel, the second shaft configured to be received in a second locating opening in the panel, wherein the second shaft is undersized relative to the second locating opening to allow a limited amount of floating movement in the second locating opening in a float direction perpendicular to the mating direction, the second biasing member forward biasing the cable connector and being compressible in a rearward compression direction parallel to the mating direction.

18. The connector assembly of claim 16, wherein the shaft includes a head, a stem extending rearward from the head, and a boss extending forward from the head, the head being received in the frame, the stem holding the biasing member, the frame configured to slide along the stem as the biasing member is compressed, wherein the boss passes through the locating opening to interface with the support element, the boss being movable in the locating opening in the float direction.

19. A communication system comprising:
a cartridge having panels forming a chamber, the panels including a front panel, the cartridge including ports in the front panel at a front of the cartridge;
connector assemblies received in the ports for mating with mating connector assemblies, each connector assembly including a connector holder, a cable connector held by the connector holder, and a mounting assembly for mounting the connector holder and the cable connector to the cartridge,
each connector holder having a frame defining a connector chamber, the frame extending between a front and a rear of the connector holder, the frame including an upper frame member, a lower frame member, and first and second side frame members extending between the upper and lower frame members to define the connector chamber;
each cable connector received in the corresponding connector chamber, each cable connector including a connector housing holding contact assemblies, each contact assembly including a signal contact and a cable terminated to the signal contact, the signal contact configured to be mated with a mating signal contact of a mating connector in a mating direction; and
each mounting assembly including a shaft, a biasing member operably coupled between the connector holder and the shaft, and a support element configured to be operably coupled between the shaft and the panels of the cartridge to support the shaft relative to the panels, the shaft configured to be received in a locating opening, wherein the shaft is undersized relative to the locating opening to allow a limited amount of floating movement in the locating opening in a float direction perpendicular to the mating direction to allow the connector holder and the cable connector to move relative to the front panel, the biasing member forward biasing the cable connector and being compressible in a rearward compression direction parallel to the mating direction to allow the connector holder and the cable connector to move rearward relative to the front panel.

20. The communication system of claim 19, wherein the shaft includes a head, a stem extending rearward from the head, and a boss extending forward from the head, the head being received in the frame, the stem holding the biasing member, the frame configured to slide along the stem as the biasing member is compressed, wherein the boss passes through the locating opening to interface with the support element, the boss being movable in the locating opening in the float direction.

21. The communication system of claim 19, further comprising a guide pin coupled to the frame and extending forward of the front panel, the guide pin configured to engage a guide module of the mating connector assembly to guide mating of the mating connectors with the cable connectors.
